(19) United States
(12) Patent Application Publication
(10) Pub. No.: US 2011/0080345 A1
(43) Pub. Date: Apr. 7, 2011

(54) LETTER INPUT METHOD AND SYSTEM FOR MOBILE TERMINAL

(75) Inventors: Kyung Jae JUN, Gumi-si (KR); Jeong Hoon KIM, Gumi-si (KR)

(73) Assignee: SAMSUNG ELECTRONICS CO. LTD., Suwon-si (KR)

(21) Appl. No.: 12/894,687

(22) Filed: Sep. 30, 2010

(30) Foreign Application Priority Data
Oct. 6, 2009 (KR) 10-2009-0094683

(51) Int. Cl. G06F 3/02; H03K 17/94

(52) U.S. Cl. 345/169; 341/22

(57) ABSTRACT

A letter input method and system for inputting a sequence of letters are provided. The letter input method includes activating a toggle input mode in response to a stroke on one of toggle keys, detecting an input event on a letter key in the toggle input mode, and inputting a letter which is fixed to the letter key in association with the toggle key activated in the toggle input mode among multiple letters assigned to letter keys.

### PRIORITY

This application claims the benefit under 35 U.S.C. §119(a) of a Korean patent application filed on Oct. 6, 2009 in the Korean Intellectual Property Office and assigned Serial No. 10-2009-0094683, the entire disclosure of which is hereby incorporated by reference.

### BACKGROUND OF THE INVENTION

1. Field of the Invention

The present invention relates to a mobile terminal. More particularly, the present invention relates to a letter input method and system for inputting a sequence of letters in a mobile terminal having a plurality of keys with multiple letters assigned to each key.

2. Description of the Related Art

With a rapid advance in electronic technologies and diversification of functions integrated into electronic devices, various types of user interfaces have been developed along with interface-specific functions. Mobile terminals now offer a touchscreen which functions as a display and an input device, simultaneously.

The mobile terminals integrate various supplementary functions as well as basic communication functions. Among the supplementary functions, a short messaging function allows a user to communicate messages anytime and anywhere.

Due to a slim and compact design, the mobile terminals are restricted in space for arranging various kinds of keys. Accordingly, multiple letters and/or numbers are assigned to one key. Even though there may be differences in key arrangements depending on the manufacturer's design, most of the mobile terminals are provided with a restricted number of keys with multiple letters assigned thereto.

In order for the user to write a message with multi-letter keys, the user has to press the same keys repeatedly for inputting one of the letters assigned to the same key, resulting in user inconvenience and an increased amount of time for message composition.

Therefore, a need exists for a method and system for inputting letters in a mobile terminal with a reduced number of key inputs.

### SUMMARY OF THE INVENTION

An aspect of the present invention is to address at least the above-mentioned problems and/or disadvantages and to provide at least the advantages described below. Accordingly, an aspect of the present invention is to provide a letter input method and system for a mobile terminal that is capable of improving user convenience.

Another aspect of the present invention is to provide a letter input method and system for a mobile terminal that is capable of facilitating message composition by reducing a number of strokes per multi-letter key.

Still another aspect of the present invention is to provide a letter input method and system for a mobile terminal that is capable of simplifying a letter input process with the multi-letter keys.

Yet another aspect of the present invention is to provide a letter input method and system for a mobile terminal that is capable of facilitating letter input with a touchscreen.

A further aspect of the present invention is to provide a letter input method and system for a mobile terminal that is capable of facilitating letter input with a keypad.

Another aspect of the present invention is to provide a letter input method and system for a mobile terminal having a touchscreen that is capable of facilitating letter input by reducing a number of touches on the multi-letter keys.

Still another aspect of the present invention is to provide a letter input method and system for a mobile terminal having a touchscreen that is capable of facilitating letter input by toggling multiple letters assigned to a key region.

In accordance with an aspect of the present invention, a letter input method for a mobile terminal is provided. The method includes activating a toggle input mode in response to a stroke on one of toggle keys, detecting an input event on a letter key in the toggle input mode, and inputting a letter which is fixed to the letter key in association with the toggle key activated in the toggle input mode among multiple letters assigned to letter keys.

In accordance with another aspect of the present invention, a letter input system for a mobile terminal is provided. The system includes a letter key region including a plurality of letter keys, each key assigned at least one letter, a toggle key region including at least one toggle key assigned an index representing an order of one of the at least one letter assigned to each letter key, and a display region for illustrating letters input using the at least one toggle key and the letter keys.

The display region may display, if an input event occurs repeatedly on a letter key while the toggle input mode is activated, the letter assigned to the letter key in an order represented by the index of the toggle key which is currently activated in the toggle input mode as many times as the number of repetitions of the input event.

A number of the at least one toggle key may be equal to a maximum number of letters assigned to a single letter key.

The letter key region, the toggle key region, and the display region may be provided on one of a display means and an input means of the mobile terminal.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a diagram illustrating mobile terminals to which a letter input system is applied according to an exemplary embodiment of the present invention;

FIGS. 2A-2B are diagrams illustrating an input method for inputting a letter in a mobile terminal method according to an exemplary embodiment of the present invention;

FIG. 3 is a flowchart illustrating a letter input method according to an exemplary embodiment of the present invention;

FIGS. 4A-4C are diagrams illustrating an input method for inputting a sequence of letters in a mobile terminal according to an exemplary embodiment of the present invention;

FIGS. 5A-5C are diagrams illustrating an input method for inputting a sequence of letters in a mobile terminal according to an exemplary embodiment of the present invention; and

FIG. 6 is a block diagram illustrating a configuration of a mobile terminal according to an exemplary embodiment of the present invention.

Throughout the drawings, it should be noted that like reference numbers are used to depict the same or similar elements, features, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

Exemplary embodiments of the present invention provide a letter input method and system for a mobile terminal. According to the exemplary embodiments of the present invention, an input means is provided with a toggle key region and a letter key region to minimize a number of actions required for inputting a letter with a multi-letter key, resulting in a reduction of input time and errors.

The letter key region includes a plurality of multi-letter keys of which each key is assigned multiple letters. In an exemplary embodiment of the present invention, the multiple letters assigned to a key are numbered by 1 to 3 (or 4) in alphabetical order such that it is possible to input a letter quickly using the letter key region and toggle key region.

In an exemplary implementation, the mobile terminal operates in one of two input modes, such as, a toggle input mode in which the toggle key region and the letter key region are activated and a normal input mode in which only the letter key region is activated. In an exemplary implementation, letter input manipulation may become easier with a combination of the toggle input mode and the normal input mode.

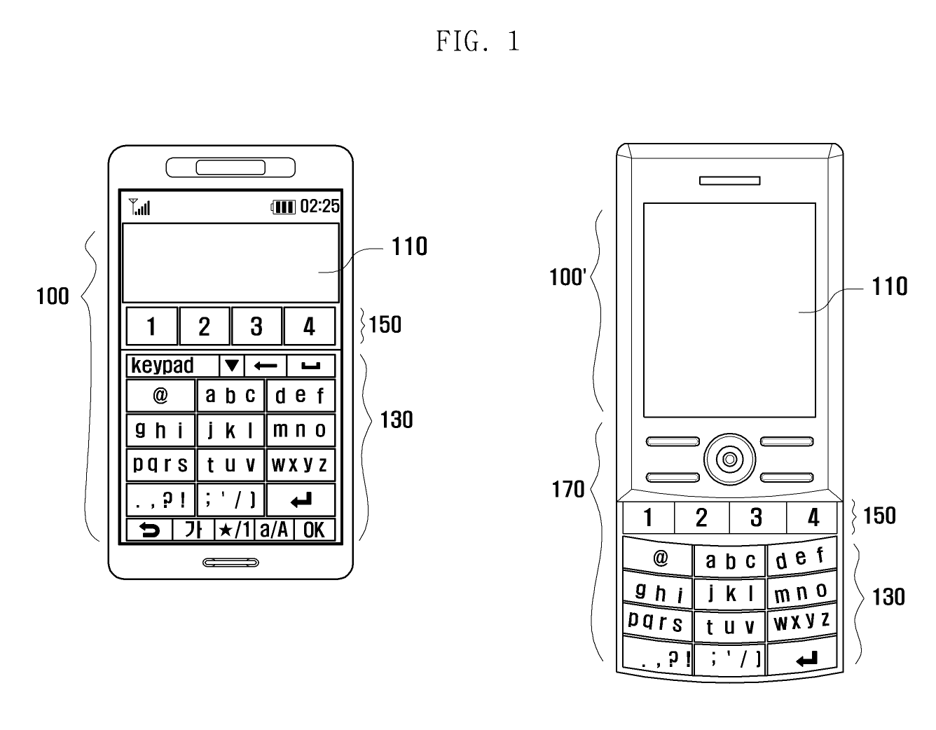

The letter input system for a mobile terminal is described in more detail below with reference to FIG. 1. Although the description is directed to the letter input system implemented in a bar type mobile terminal equipped with a full touchscreen and a slide type mobile terminal equipped with a keypad, the present invention is not limited thereto. For example, various types of mobile terminals may be implemented with or without modifications.

FIG. 1 is a diagram illustrating mobile terminals to which a letter input system is applied according to an exemplary embodiment of the present invention.

As illustrated in FIG. 1, the letter input system may be applied to a full touchscreen mobile terminal having a touchscreen and a slide type mobile terminal having a keypad. Here, the type of the mobile terminal and the key arrangement of the letter input system may be changed depending on the mobile manufacturer.

Referring to FIG. 1, the mobile terminals include a touchscreen display 100, a display 100′ which may be equipped with touchscreen functionality and implemented with a Liquid Crystal Display (LCD) panel or an Organic Light Emitting Diode (OLED) panel, and a keypad 170 which is normally illustrated in a bar type, a folder type, and a slide type mobile terminals.

The mobile terminals further include a text window 110 for displaying text input by the user, a letter key region 130 including a plurality of multi-letter keys, and a toggle key region 150 including toggle keys to provide mappings to letters of each multi-letter key in a toggle input mode. The letter key region 130 is provided with a plurality of multi-letter keys, and each multi-letter key is assigned multiple letters. The toggle key region 150 is provided with at least one toggle key, and the number of toggle keys is determined to be equal to the number of letters assigned to the selected multi-letter key. In an exemplary implementation, the mobile terminal may operate in the toggle mode in which the user may input one of the multiple letters assigned to a key directly by means of the toggle keys in the toggle key region 150.

Although the letter key region 130 and the toggle key region 150 are arranged such that the toggle key region 150 is positioned at the top side of the letter key region 130 in FIG. 1, the toggle key region 150 may be arranged at a bottom, a left, or a right side of the key selection letter key region 130.

In an exemplary implementation, the mobile terminal may operate in one of two input modes, such as, a toggle input mode in which the toggle key region and the letter key region are activated and a normal input mode in which only the letter key region is activated.

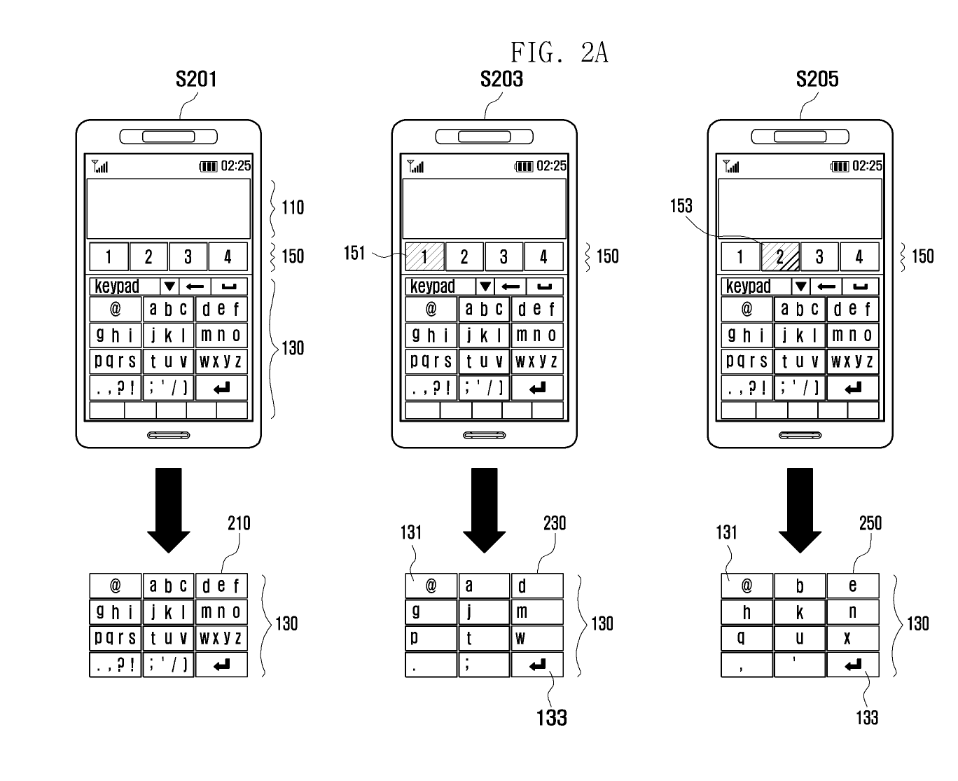

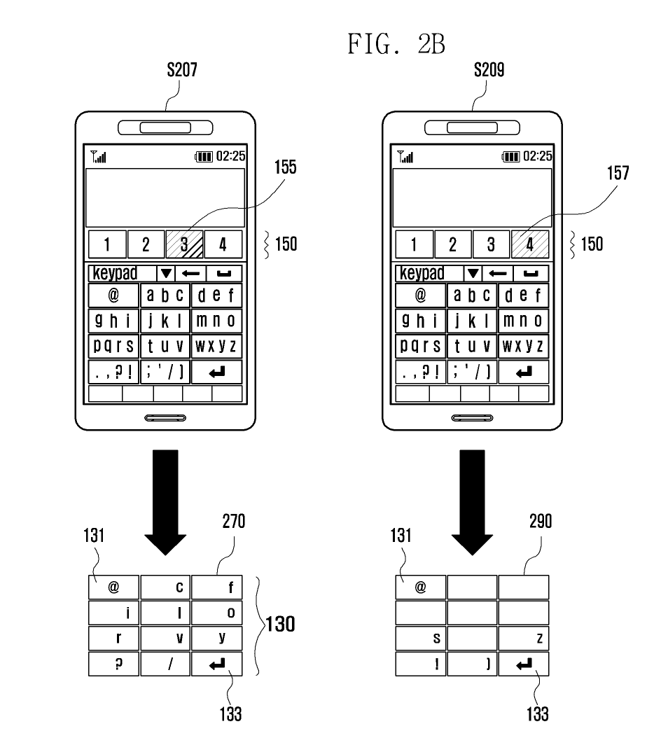

In the normal input mode, a letter is input by stroking a corresponding multi-letter key repeatedly until a target letter appears in the text window 110. In the toggle input mode, a letter is input by selecting one of the toggle keys of which number is identical with an order of the target letter among the letters assigned to the multi-letter key in alphabetical order. The letter input mechanism with the toggle key region 150 and letter key region 130 will be described in more detail below with reference to FIGS. 2A-2B.

FIGS. 2A-2B are diagrams illustrating an input method for inputting a letter in a mobile terminal according to an exemplary embodiment of the present invention. FIGS. 2A-2B illustrate how to switch between input modes and interoperation of the toggle key region 150 and the letter key region 130.

Referring to FIGS. 2A-2B, reference number S201 denotes a front view of the mobile terminal having a screen displayed when the mobile terminal operates in a normal input mode. In the normal input mode, the toggle keys in the toggle key region 150 are disabled such that no input is allowed by the toggle keys. In this case, the user may input a target letter by stroking a corresponding key repeatedly. In order to input a letter which is assigned a low priority order on a multi-letter key in the normal input mode, the user must repeat the stroking of the corresponding key until the target letter is illustrated in the text window 110. For example, in order to input the letter “c”, the user must stroke the key that is assigned the letters “a”, “b”, and “c” three times.

Reference number S203 denotes a front view of the mobile terminal having a screen displayed when the mobile terminal operates in the toggle input mode, more particularly when the first toggle key 151 is activated in the toggle key region 150. If the first toggle key 151 is selected by the user, each multi-letter key is dedicated to the letter having a first order among the multiple letters assigned thereto in the letter key region 130 as denoted by reference number 230. In this case, the multi-letter keys are fixed to input the letters of the first order.

At this time, other letters having low priority orders are disabled at the corresponding multi-letter key. For example, if the first toggle key 151 is selected, the “abc” key is fixed to input only the letter “a” among the letters “a”, “b”, and “c” assigned thereto, and the “pqrs” key is fixed to input only the letter “p” among the letters “p”, “q”, “r”, and “s” assigned thereto.

If the user strokes the “abc” key three times while the toggle input mode is activated with the selection of the first toggle key 151, the user input the letter “a” three times. Accordingly, the user may input a sequence of letters “aaa” with four quick key strokes.

In the normal input mode, it is required to stroke the “abc” key 3 to 5 times for inputting the sequence of letters “aaa”. Even in a case where the sequence of letters “aaa” may be input by 3 strokes, the user must wait until the “a” previously input is confirmed as the intended input for a preset duration before it is possible to input the next letter, resulting in an input delay.

In a case of inputting the series of letter “aaa” with 5 strokes, the user strokes the “abc” key once to select the letter “a” and then a navigation key twice to confirm the selected letter “a” as intended input. This process is repeated twice for inputting the first two letters of “a”, resulting in an increase in the number of key strokes. In contrast, the letter input method according to an exemplary embodiment of the present invention allows inputting a sequence of letters with a minimum number of key strokes in the toggle mode.

Reference number S205 denotes a front view of the mobile terminal having a screen displayed when the mobile terminals operate in the toggle input mode, more particularly when the second toggle key 153 is activated in the toggle key region 150. If the second toggle key 153 is selected by the user, each multi-letter key is dedicated to a letter having a second order among multiple letters assigned thereto in the letter key region 130 as denoted by reference number 250. In this case, the multi-letter keys are fixed to input the letters of the second order.

At this time, other letters having the priority orders higher or lower than the second priority order are disabled at the corresponding multi-letter key. For example, if the second toggle key 153 is selected, the “abc” key is fixed to input only the letter “b” among the letters “a”, “b”, and “c” assigned thereto, and the “pqrs” keys is fixed to input only the letter “q” among the letters “p”, “q”, “r”, and “s” assigned thereto. Here, special keys 131 and 133 may be configured to be activated in the toggle input mode or only when the toggle input mode is activated with a specific toggle key.

If the user strokes the “abc” key three times while the toggle input mode is activated with the selection of the second toggle key 153, this means that the user input the letter “b” three times. Accordingly, the user may input a sequence of letters “bbb” by four quick key strokes.

In the normal input mode, it is required to stroke the “abc” key 6 to 8 times for inputting the sequence of letters “bbb”. In a case where the sequence of letters “bbb” is input by 6 strokes, the user strokes the “abc” key twice to display the letter “b” and waits until the “b” is confirmed as the intended input for a preset duration before it is possible to input the next letter, resulting in an input delay.

In a case where the sequence of letters “bbb” is input by 8 strokes, the user strokes the “abc” key twice to select the letter “b” and then strokes a navigation key to confirm that the selected letter “b” is an intended input. This process is repeated twice for inputting the first two letters of “b”, resulting in an increase in the number of key strokes. In contrast, the letter input method according to an exemplary embodiment of the present invention allows for inputting a sequence of letters with a minimum number of key strokes in the toggle mode.

In the same manner, the letters may be input with a minimum number of key strokes in the toggle input modes activated with the third and fourth toggle keys 155 and 157 as illustrated in the front view images denoted by reference numbers S207 and S209 and the letter key regions 270 and 290.

Although four toggle keys 151, 153, 155, and 157 are depicted in FIGS. 2A-2B, the number of toggle keys may be changed depending on the key arrangement and the number of letters assigned to the keys. For example, if a maximum number of letters assigned to the multi-letter keys is three, it is preferred that the number toggle keys in the toggle key region 150 is three.

As described above, if one of the toggle keys is selected in the input mode, a toggle input mode is activated with the multi-letter keys of which each key is dedicated to one of the letters assigned thereto according to the selected toggle key such that the user input the target letter quickly.

Procedures for inputting letters in the normal input mode and the toggle input mode are described below in more detail. However, the letter input method of an exemplary embodiment of the present invention is not limited thereto. For example, the letter input method may be implemented with or without modifications.

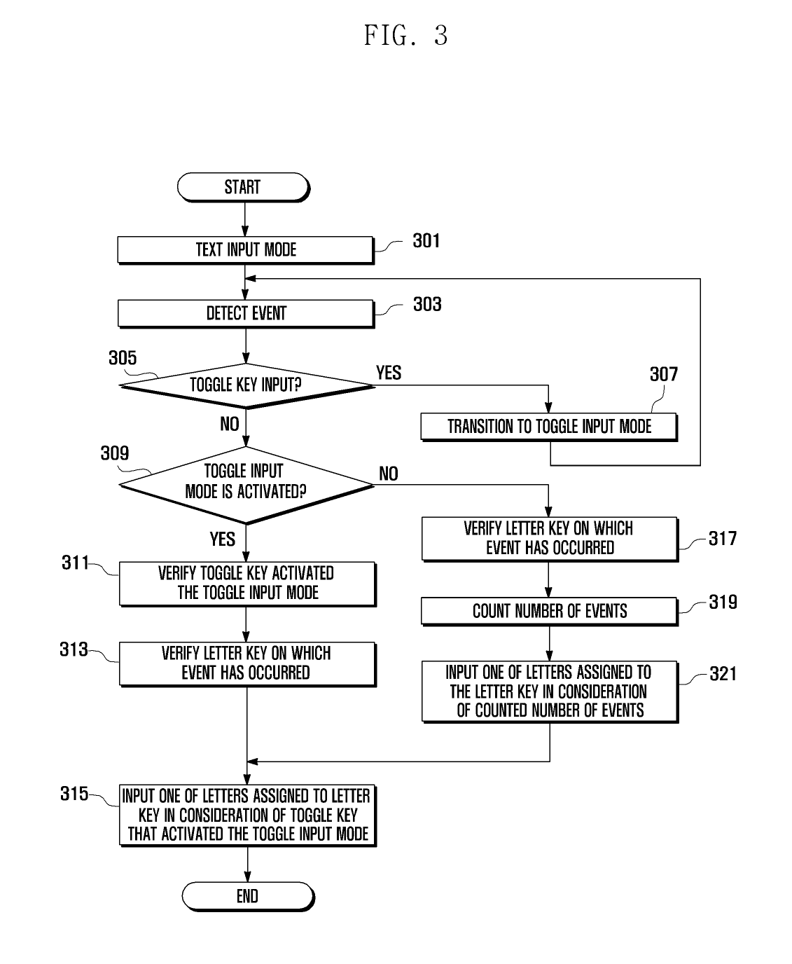

FIG. 3 is a flowchart illustrating a letter input method according to an exemplary embodiment of the present invention.

Referring to FIG. 3, the mobile terminal activates a text input mode in response to a user request in step 301. The text input mode is activated when a text-related application (i.e., text messaging, email, memo, and the like) is running.

In the text input mode, the mobile terminal monitors to detect an event in step 303. Once an event is detected, the mobile terminal determines whether the event is a toggle key selection event in step 305.

If it is determined that the event is a toggle key selection event, the mobile terminal verifies the toggle key on which the toggle key selection event is detected and enters the toggle key-specific toggle input mode in step 307. Here, the toggle key-specific toggle input mode entry may be a transition from a normal input mode or another toggle key-triggered toggle input mode. If a key input event is detected in the letter key region after entering the current toggle key-specific toggle input mode, the process returns to step 303.

If it is determined that the event is not the toggle key selection event in step 305, the mobile terminal determines whether the current text input mode is a toggle input mode in step 309.

If it is determined that the current text input mode is a toggle input mode, the mobile terminal verifies the toggle key that triggered the current toggle input mode in step 311. Next, the mobile terminal verifies the multi-letter key on which the event is detected in step 313 and inputs one of the letters assigned to the multi-letter key which is dedicated to the multi-letter key by the toggle key that triggered the current toggle input mode in step 315. That is, the mobile terminal displays the letter of which priority order in the selected multi-letter key is identical with that of the toggle key that triggered the current toggle input mode in the text window 110.

If it is determined that the current text input mode is not a toggle input mode in step 309, the mobile terminal verifies the multi-letter key on which the event is detected in step 317 and counts a number of strokes that occurred in the event in step 319. The mobile terminal inputs a letter of which priority order in the multi-letter key corresponds to the number of strokes among the letters assigned to the multi-letter key in step 321. That is, the mobile terminal displays the letter of which priority order in the selected multi-letter key is identical with that of the number of strokes in the text window 110.

The letter input method as described above with reference to FIGS. 1 to 3 is described below in association with an exemplary case. However, the letter input method of the present invention is not limited thereto. For example, the letter input method may be implemented with or without modifications.

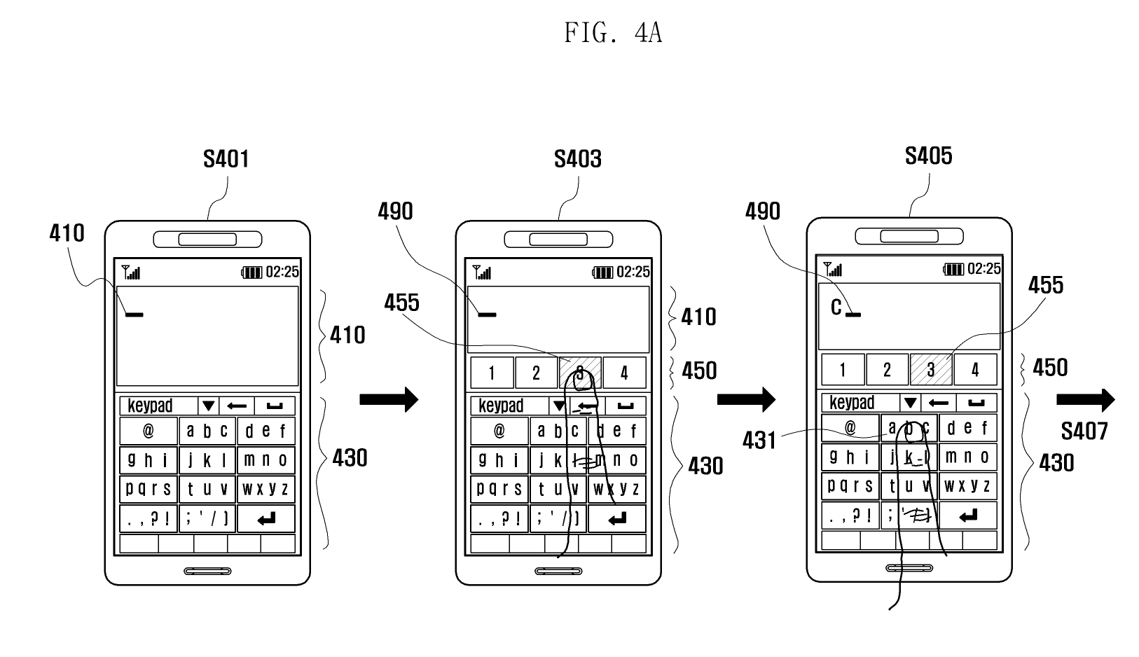

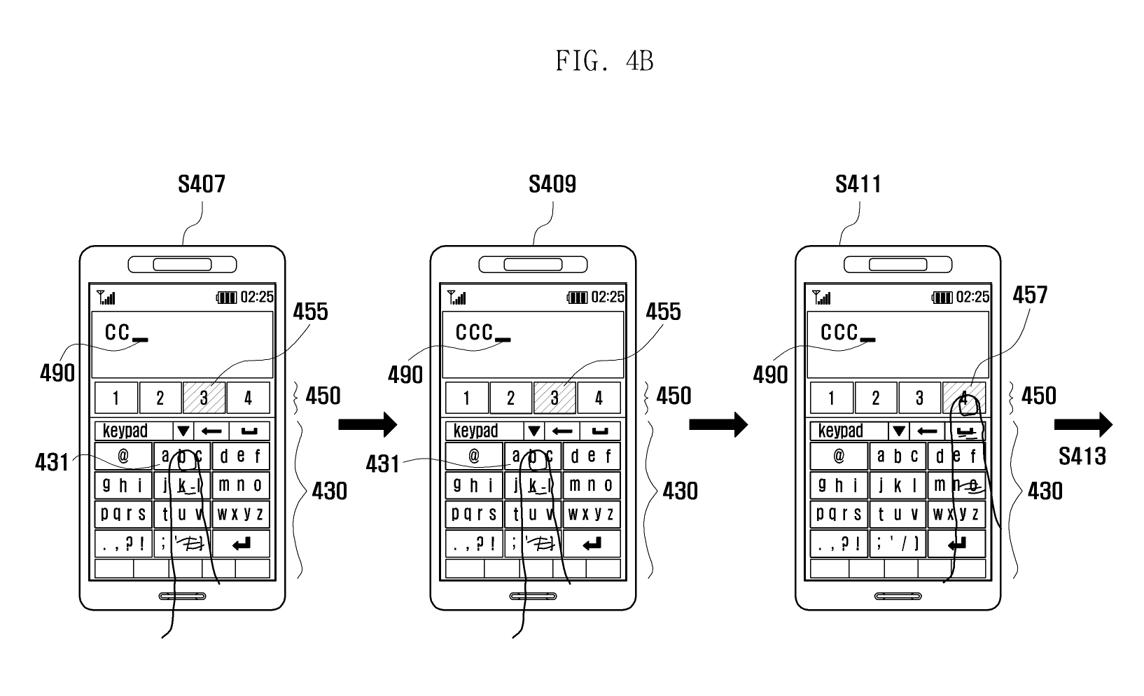

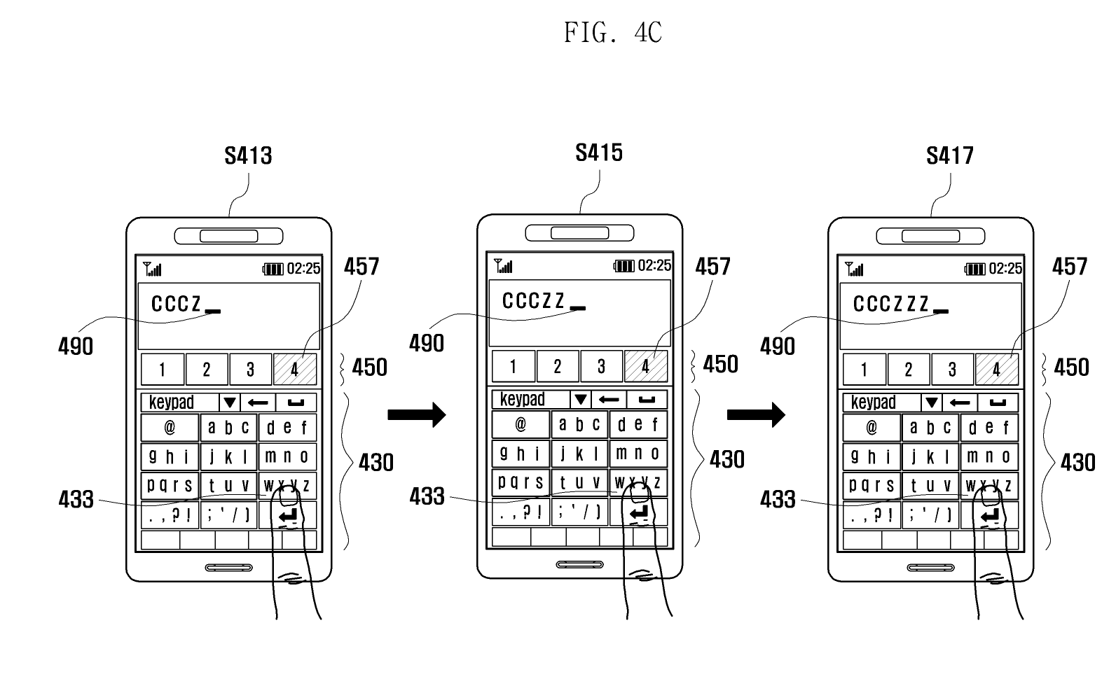

FIGS. 4A-4C are diagrams illustrating an input method for inputting a sequence of letters in a mobile terminal according to an exemplary embodiment of the present invention. FIG. 4 is depicted to illustrate operations for inputting an exemplary sequence of letters “ccczzz” according to an exemplary embodiment of the present invention.

Referring to FIG. 4A, reference number S401 denotes a front view of the mobile terminal illustrating a screen in which the toggle key region is disabled. In an exemplary implementation, the toggle key region may be configured to be hidden or appear according to whether the toggle input mode is activated or deactivated. In a case where the toggle key region is hidden, the text window 410 is expanded to the area whether the toggle key region has disappeared. The text window 410 is provided with a cursor 490 indicating the letter input position.

In a case where the mobile terminal is in a normal input mode as illustrated in the front view image S401, the user may input the sequence of letters “ccczzz”. In order to input the sequence of letters “ccczzz” in the normal input mode, a total of 21 strokes are required. In order to input the letter “c”, a total of 3 strokes are required on the “abc” key because the “abc” key suggests “a” for the first stroke, “b” for the second stroke” and “c” for the third stroke”. Accordingly, a total of 9 strokes are required to input the sequence of letters “ccc”. Also, in order to input the letter “z”, a total of 4 strokes are required on the “wxyz” key because the “wxyz” key suggests “w” for the first stroke, “x” for the second stroke, “y” for the third stroke, and “z” for the fourth stroke. Accordingly, a total of 12 strokes are required to input the sequence of letters “zzz”. As a consequence, a total of 21 strokes (i.e., 9 strokes for three c's and 12 strokes for three z's) are required to input the sequence of letters “ccczzz”.

Reference number S403 denotes a front view of the mobile terminal illustrating a screen in which the toggle key region 450 is enabled in response to a user request. The user may enable the toggle key region 450 with a preset input gesture.

In a case where the mobile terminal is in the toggle input mode as illustrated in the front view image S403, the user may fix the “abc” key to the letter “c” by selecting the third toggle key 455 which is designated to fix the multi-letter keys arranged in the letter key region 430 to their thirdly assigned letters. Once the multi-letter keys are fixed to the thirdly assigned letters, the user may input letter “c” by stroking the “abc” key 431 one time as illustrated in the front view image S405.

Here, the third toggle key may be selected by a gesture such as a touch, a tap, a double tap, and the like, on the touchscreen. In a case where the mobile terminal is implemented with a keypad, the key selection may be made by pressing a key designated for activating the toggle key 455. The toggle key 455 may be disabled in response to a key input (e.g., by pressing the key designated for deactivating the toggle key 455).

Once the third toggle key is activated as illustrated in the front view image S405, the user inputs the first letter “c” of the sequence of letters “ccczzz” by stroking the “abc” key 431 one time. If an input event is detected on the “abc” key 431, the mobile terminal displays the first letter “c” in the text window 410 as illustrated in the front view image S405. If the first letter “c” is displayed in the text window 410, the cursor 490 shifts to the next letter input position. The cursor shifts to the right whenever a letter is input or may be omitted depending on the configuration.

Referring to FIG. 4B, the user inputs the second letter “c” of the sequence of letters “ccczzz” by stroking the “abc” key 431 one more time. If the input event is detected on the “abc” key 431, the mobile terminal displays the second letter “c” along with the first letter “c”, i.e., “cc”, in the text window 410 as illustrated in the front view image S407. If the second letter “c” is displayed in the text window 410, the cursor 490 shifts to the next letter input position.

The user inputs the third letter “c” of the sequence of letters “ccczzz” by stroking the “abc” key 431 one more time. If the input event is detected on the “abc” key 431, the mobile terminal displays the third letter “c” in the text window 410 along with the first letter and second letter “cc”, i.e., “ccc”, as illustrated in the front view image S409.

In order to input the fourth letter “z” of the sequence of letters “ccczzz”, the user selects the fourth toggle key 457, as illustrated in the front view image S411, because the letter “z” is fourthly assigned to the “wxyz” key. In response to the fourth toggle key selection, the multi-letter keys arranged in the letter key regions 430 are fixed to their fourthly assigned letters.

Referring to FIG. 4C, once the multi-letter keys are fixed to the fourthly assigned letters in the fourth toggle key-triggered toggle input mode, the user inputs the fourth letter “z” of the sequence of letters “ccczzz” by stroking the “wxyz” key 433 one time. If the input event is detected on the “wxyz” key 433, the mobile terminal displays the fourth letter “z” in the text window 410 along with the previously input letters “ccc”, i.e., “cccz”, as illustrated in the front view image S413.

The user inputs the fifth letter “z” of the sequence of letters “ccczzz” by stroking the “wxyz” key 433 one more time. If the input event is detected on the “wxyz” key 433, the mobile terminal displays the fifth letter “z” in the text window 410 along with the previously input letters “cccz”, i.e., “ccczz”, as illustrated in the front view image S415.

The user inputs the sixth letter “z” of the sequence of letters “ccczzz” by stroking the “wxyz” key 433 one more time. If the input event is detected on the “wxyz” key 433, the mobile terminal displays the sixth letter “z” in the text window 410 along with the previously input letters “ccczz”, i.e., “ccczzz”, as illustrated in the front view image S417.

As described with reference to FIGS. 4A-4C, in order to input the sequence of letters “ccczzz” in the toggle input mode according to an exemplary embodiment of the present invention, a total of 8 strokes are required. In order to input the first three letters “ccc”, it is required to stroke the third toggle key 455 one time and the “abc” key 231 three times. That is, the first three letters “ccc” may be input only with 4 strokes. Also, in order to input the last three letters “zzzz”, it is required to stroke the fourth toggle key 457 one time and the “wxyz” key 433 three times. That is, the last three letters “zzz” may be input only with 4 strokes.

Accordingly, the toggle input mode-based letter input method according to an exemplary embodiment of the present invention may reduce the number of strokes required for the inputting of a series of letters “ccczzz” as many as 13 strokes compared to the normal input mode, resulting in a reduction of text input time.

Although a description has been made under the assumption that the toggle input mode is maintained until a toggle input mode transition request or a toggle input mode deactivation request is input, the present invention is not limited thereto.

In an exemplary case of supporting multi-touch input, a user may input one or more letters by activating the toggle input mode with a first touch made on an intended toggle key and make a second touch on one or more letter keys while holding the first touch on the intended toggle key. The mobile terminal maintains the toggle input mode triggered by a specific toggle key while the toggle key is held by the first touch and displays the letter to which the multi-letter key, on which the second touch is made, is fixed by a hold of the current toggle key. The toggle input mode triggered with a specific toggle key may be deactivated by releasing the first touch from the toggle key, and the letter input process may be continued in the normal input mode or in the toggle input mode triggered with another toggle key.

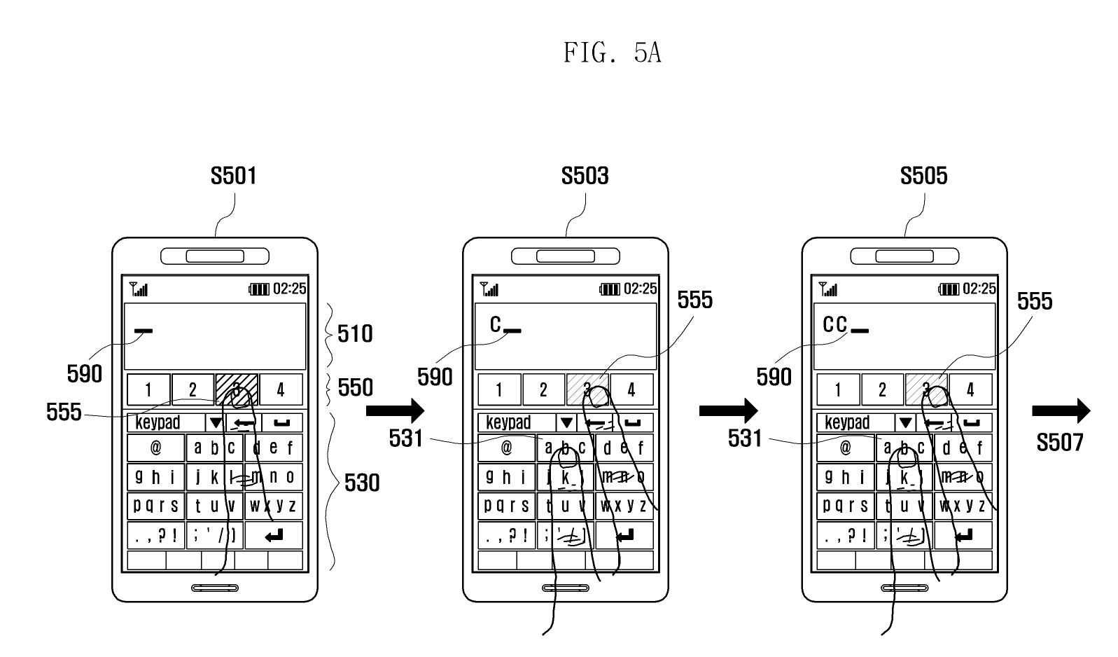

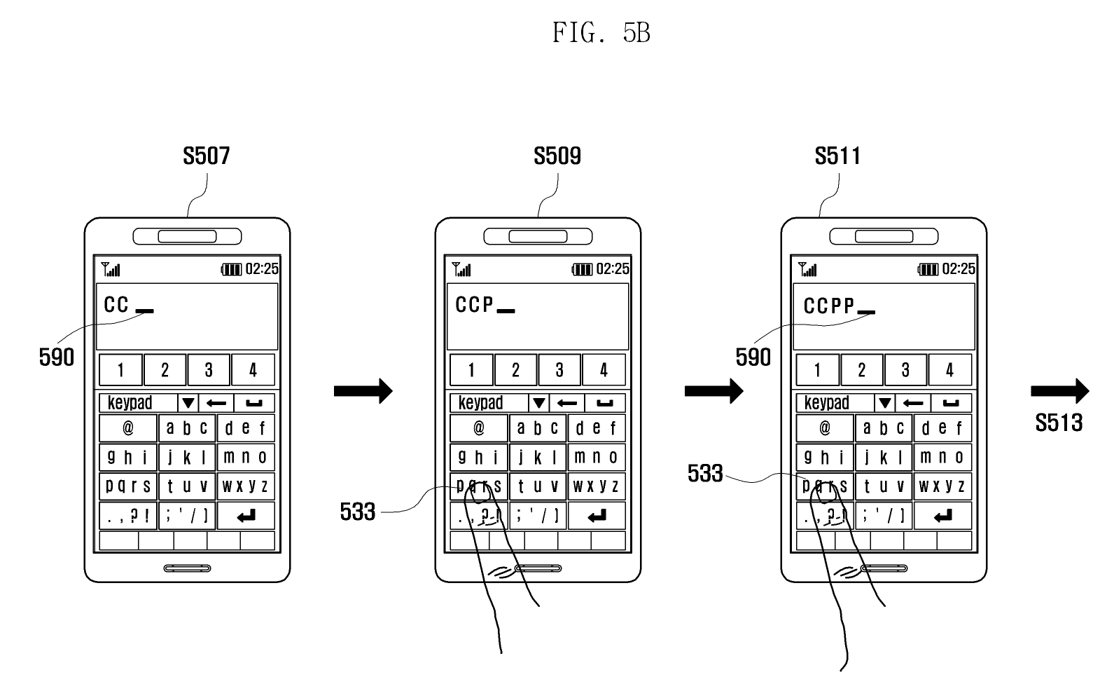

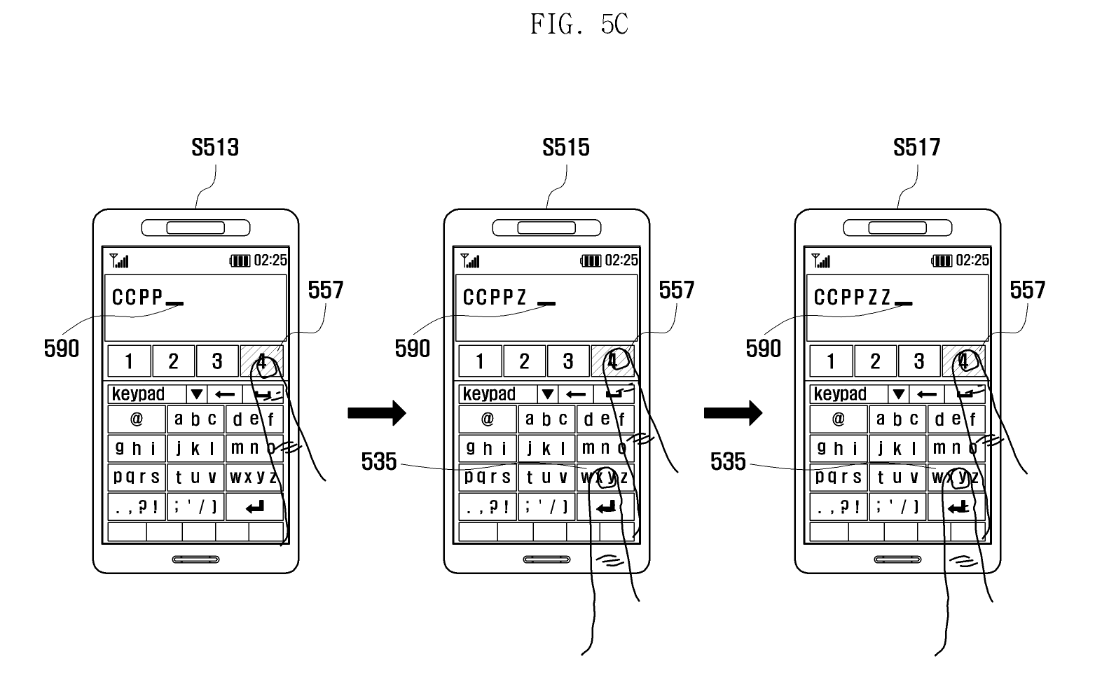

FIGS. 5A-5C are diagrams illustrating a method for inputting a sequence of letters in a mobile terminal according to an exemplary embodiment of the present invention. FIG. 5 is depicted to illustrate operations for inputting an exemplary sequence of letters “ccppzz” with a multi-touch input mechanism.

Referring to FIG. 5A, in order to input the first letter “c” of the sequence of letters “ccppzz” in a text input mode, the user makes a first touch on the third toggle key 555 as illustrated in the front view image S501 of the mobile terminal because the letter “c” is thirdly assigned to the “abc” key. If the first touch is detected on the third toggle key 555, the mobile terminal enters the toggle input mode. At this time, a cursor 590 is displayed in the text window 510 to indicate an input letter position.

While keeping the first touch on the third toggle key 555 to maintain the toggle input mode, the user makes a second touch on the “abc” key 531 to which the letter “c” is thirdly assigned. If the second touch is detected on the “abc” key 531 while the first touch is kept on the third toggle key 555, the mobile terminal inputs the letter “c” to be displayed in the text window 510 as illustrated in the front view image S503.

If a letter is input, the cursor 510 shifts to indicate the next letter input position. The cursor shifts to the right whenever a letter is input or may be omitted depending on the configuration.

Next, in order to input the second letter “c” of the sequence of letters “ccppzz”, the user makes the second touch on the “abc” key 531 one more time while keeping the first touch on the third toggle key 555. If the second touch is detected on the “abc” key 531, the mobile terminal displays the second letter “c” in the text window 510 along with the first letter “c”, i.e., “cc”, as illustrated in the front view image S505.

Referring to FIG. 5B, in order to prepare input of the third letter “p” of the sequence of letters “ccppzz”, the user releases the first touch from the third toggle key 555 and the second touch from the “abc” key 531 as illustrated in the front view image S507. If the second touch made in the toggle key region 555 is released, the toggle input mode is deactivated.

In order to input the third letter “p” of the sequence of letters “ccppzz”, the user makes a touch on the “pqrs” key 533 one time as illustrated in the front view image 509. If the single touch is detected on the “pqrs” key 533 in the normal input mode, the mobile terminal interprets this touch event into a command for inputting the letter “p” which firstly assigned to the “pqrs” key 533 and thus displays the letter “p” in the text window 510 along with the previously input letters “cc”, i.e., “ccp”, as illustrated in the front view image S509.

In order to input the fourth letter “p” of the sequence of letters “ccppzz”, the user makes a touch on the “pqrs” key 533 one more time. If the signal touch is detected on the “pqrs” key 533, the mobile terminal displays the fourth letter “p” in the text window 510 along with the previously input letters “ccp”, i.e., “ccpp”, as illustrated in the front view image S511.

Although it is described above that the third and fourth letters “pp” are input in the normal input mode, these letters may also be input in the toggle input mode by making the first touch on the first toggle key and the second touch on the “pqrs” key twice for fast continuous input. With the activation of the toggle mode triggered by the first toggle key, the mobile terminal determines the following individual touches described below as the individual letter input commands and thus inputs the letter “p” twice.

Referring to FIG. 5C, in order to input the fifth letter “z” of the sequence of letters “ccppzz”, the user makes the first touch on the fourth toggle key 557 in the toggle key region 550 to activate the toggle input mode as illustrated in the front view image 513 because the letter “z” is fourthly assigned to the “wxyz” key. If the first touch is detected on the fourth toggle key 557, the mobile terminal enters the toggle input mode triggered by the fourth toggle key 557.

While keeping the first touch on the fourth toggle key 557 to maintain the toggle input mode, the user makes the second touch on the “wxyz” key 535 to which the letter “z” is fourthly assigned as illustrated in the front view image S515. If the second touch is detected on the “wxyz” key 535 while the first touch is kept on the fourth toggle key 557, the mobile terminal displays the fifth letter “z” in the text window 510 along with the previously input letters “ccpp”, i.e., “ccppz” as illustrated in the front view image S515.

In order to input the sixth letter “z” of the sequence of letters “ccppzz”, the user makes the second touch on the “wxyz” key 535 one more time while keeping the first touch on the fourth toggle key 557. If the second touch is detected on the “wxyz” key 535, the mobile terminal displays the sixth letter “z” in the text window 510 along with the previously input letters “ccppz”, i.e., “ccppzz”, as illustrated in the front view image S517.

In a case of inputting the sequence of letters “ccppzz” in the normal input mode, it is required to make six touches on the “abc” key for “cc” (i.e., a total of three touches for each “b”), two touches on the “pqrs” key for “pp” (i.e., a total of one touch for each “p”), and eight touches on the “wxyz” key for “zz” (i.e., a total of four touches for each “z”).

Accordingly, the total number of touches required for inputting the sequence of letters “ccppzz” is 16 in the normal input mode. In a case of using a navigation key for completing the input of the letters whenever a letter is input, the number of touches further increases. In a case of waiting for a preset duration for completing the input of the letters whenever a letter is input, the letters input time increases significantly.

In the toggle input mode based on the multi-touch input according to an exemplary embodiment of the present invention, it is required to make three touches for inputting “cc” (i.e., one first touch on the third toggle key and two second touches on the “abc” key), three touches for inputting “pp” (i.e., one first touch on the first toggle key and two second touches on the “pqrs” key), and a total of three touches for inputting “zz” (i.e., one first touch on the fourth toggle key and two second touches on the “wxyz” key).

Accordingly, the total number of touches required for inputting the sequence of letters “ccppzz” is 9 in the toggle input mode. In a case where the sequence of letters “cc” is input in the normal input mode, the total number of touches required for inputting the sequence of letters “ccppzz” becomes 8. In this manner, the letter input method according to an exemplary embodiment of the present invention is capable of reducing the number of touches (i.e., strokes) and time required for inputting letters.

A description is made of a configuration of a mobile terminal for supporting the above-described letter input method. However, the configuration of the mobile terminal is not limited thereto. For example, the configuration may be implemented with or without modifications.

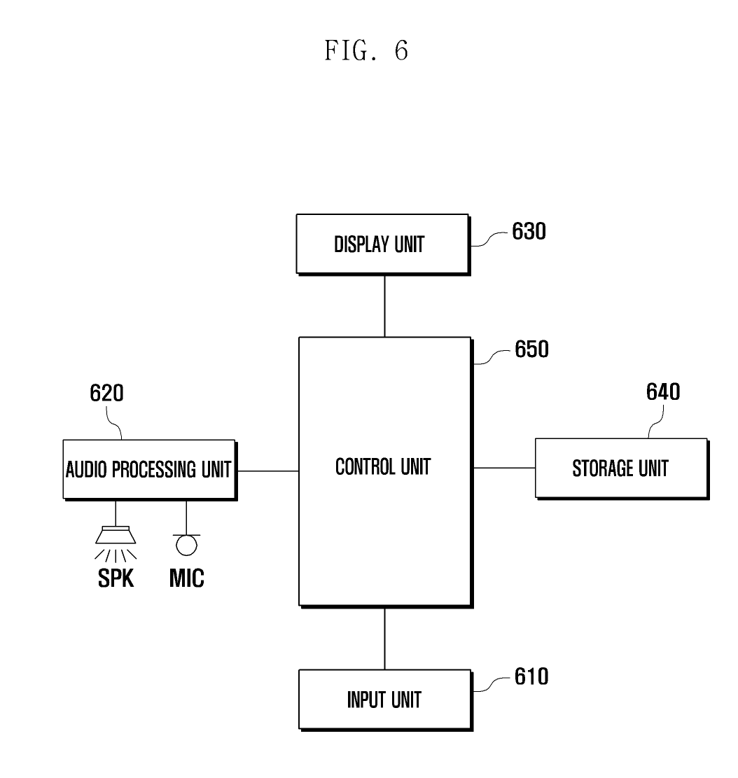

FIG. 6 is a block diagram illustrating a configuration of a mobile terminal according to an exemplary embodiment of the present invention.

Referring to FIG. 6, the mobile terminal includes an input unit 610, an audio processing unit 620, a display unit 630, a storage unit 640, and a control unit 650. The audio processing unit 620 includes a Speaker (SPK) and a Microphone (MIC). Individual function blocks of the configuration of the mobile terminal are described in more detail below.

The input unit 610 is provided with a plurality of alphanumeric keys and functions keys and transfers a signal corresponding to a key input to the control unit 650. The functions keys may be implemented in the form of navigation keys, side keys, and shortcut keys. The input unit 610 may be implemented with at least one of a touchpad, a touchscreen, a normal keypad, and a QWERTY keypad. More particularly, in an exemplary embodiment of the present invention, the input unit 610 may be provided with a toggle key region having at least one toggle key and a letter key region having a plurality of letter keys. In a case where the mobile terminal is implemented with a full touchscreen, the input unit 610 may be replaced by the full touchscreen.

The audio processing unit 620 includes the SPK for outputting audio data of the mobile terminal and the MIC receiving the audio signal including user voice. The audio processing unit 620 is electrically connected to the MIC and the SPK and outputs the audio signal input through the MIC to the control unit 620 in the form of audio data and outputs the audio signal from the control unit 650 through the SPK in the form of audible sound wave. That is, the audio processing unit 620 converts an analog audio signal input through the MIC into the digital audio signal and converts the digital audio signal input from the control unit 650 into the analog audio signal to be output through the SPK. The audio processing unit 620 may be configured to output various types of audio signals generated in the mobile terminal (e.g., an alarm signal for alarming of an entry of the toggle input mode) according to the user's selection. A specific audio signal output function such as alarm signal output may be omitted or replaced by a specific alarm action such as vibration having a specific pattern depending on the user settings or manufacturer's design.

The display unit 630 displays various screens associated with the operations of the mobile terminal. For example, the display unit 630 may display a booting progress screen, an idle mode screen, a menu screen, and a call progress screen. That is, the display unit 630 displays visual information related to a running status and operations of the mobile terminal. The display unit 630 may be implemented with an LCD panel or an OLED panel. Also, the display unit 630 may be equipped with touchscreen functionality. In this case, the display unit 630 may function as both the input means and output means. More particularly, in an exemplary embodiment of the present invention, when the display unit 630 is implemented with the touchscreen, the text input mode screen displayed in the text input mode is composed of a display region, a toggle key region, and a letter key region such that the letters input with the combination of keys arranged in the toggle key region and the letter key region is displayed in the display region. The display unit 630 may be configured such that, when a toggle input mode is activated, an alarm icon or image is displayed at a corner of the screen for alarming the entry of the toggle input mode.

The storage unit 640 may be implemented with at least one of Read Only Memory (ROM) and Random Access Memory (RAM). The storage unit 640 stores various types of data generated and used in the mobile terminal. The data can include all types of application data (e.g., text message, phonebook data, and the like) generated by the applications running in the mobile terminal and received from an external device (e.g., a base station, another mobile terminal, a personal computer, and the like). The storage unit 640 may also store settings of functions provided by the mobile terminal

The storage unit 640 may include at least one buffer for buffering the data generated by the functions that are currently executed. For example, the storage unit 640 may be provided with a buffer for buffering the data generated in the text input mode in a unit of preset data size.

The storage unit 640 may be implemented with at least one of internal memory and external memory such as a smart card. The storage unit 640 may be implemented with at least one of a ROM, a Flash Memory, a RAM, and a combination memory integrating two or more types of memories such as Multi Chip Package (MCP) memory.

The control unit 650 controls entire operations of the mobile terminal and signaling among the internal function blocks. The control unit 650 controls signaling among the input unit 610, audio processing unit 620, display unit 630, and storage unit 640.

More particularly, in an exemplary embodiment of the present invention, the control unit 650 controls the operations related to the text input process in the toggle input mode. The control unit 650 activates the toggle input mode in response to a user input detected in the toggle key region. If an event is detected to select one of the toggle keys arranged in the toggle key region, the control unit 650 controls such that the multi-letter keys arranged in the letter key region are fixed to the letters that are assigned with the same order as that of the selected toggle key.

If an event is detected in the letter key region rather than the toggle key input, the control unit 650 verifies the current input mode and processes the event depending on whether current input mode is the toggle input mode. In a case where the mobile terminal is in the toggle input mode, the control unit 650 inputs the letter to which the multi-letter key is fixed in association with the toggle key that triggered the toggle input mode.

A control sequence of the control unit 650 may be implemented as software. In this case, the mobile terminal for supporting exemplary embodiments of the present invention can be implemented without modification in hardware. The control unit 650 may control entire operations related to exemplary embodiments of the present invention as described with reference to FIGS. 1 to 5.

Although the mobile terminal is depicted schematically in FIG. 6 for simplifying the explanation, exemplary embodiments of the present invention are not limited thereto.

For example, the control unit 650 may include a baseband module which processes radio signals for mobile communication service. In this case, the mobile terminal may further include a Radio Frequency (RF) unit. The baseband module may be integrated into at least one of the control unit 650 and RF unit or implemented as a separate component.

Although not depicted in FIG. 6, the mobile terminal may include at least one of a camera module for taking a picture of a subject, an Local Area Network (LAN) module for supporting LAN communication, an Internet access module for supporting Internet accessing, a digital broadcast module for receiving and playing digital broadcast data such as Digital Multimedia Broadcasting (DMB) and Digital Video Broadcasting (DVB) data, and a short range wireless communication module such as a Bluetooth module for short range wireless communication. Although not enumerated here, other devices equivalent to the above-described function modules may be further included in the mobile terminal. Also, it is obvious to those skilled in the art that each of the internal function blocks constituting the mobile terminal may be omitted or replaced by other equivalent device.

Although descriptions have been made of the mobile terminal having a touchscreen in the exemplary embodiments of the present invention with reference to FIGS. 1 to 6, the mobile terminal may be implemented with a normal display and an input unit. For example, the mobile terminal having a display unit may be implemented with an LCD or OLED panel and at least one of a keypad and a touchpad.

That is, the mobile terminal may display the letters input by the user on the display unit and control the process for inputting the letters by manipulating the touchpad and/or keypad (i.e., the toggle key and the letter key input). For example, a letter may be input according to a combination of a letter key and a toggle key provided by the keypad. That is, the mobile terminal may be configured such that the letter input method of the present invention may be implemented with a manipulation of the keypad and/or touchpad. The letter input method may also be implemented with the assistance of the MIC and a motion sensor as a part of the input unit. For example, the toggle input mode activation and/or transition and letter input may be performed by means of a speech recognition function and a motion recognition function of the mobile terminal.

The mobile terminal of the present invention may be any of mobile communication terminals operating with communication protocols implemented in various communication systems, a Personal Multimedia Player (PMP), a Digital Broadcast Player, a Personal Digital Assistant (PDA), a music player (e.g., MP3 player), a Smartphone, and the like.

Although a description has been of the mobile terminal having a full touchscreen in the exemplary embodiments of the present invention with reference to FIGS. 1 to 6, the present invention is not limited thereto. For example, the mobile terminal may be implemented with at least one of a folder type, a bar type, and a slide type. The toggle input mode-based letter input method according to an exemplary embodiment of the present invention may be applied to large display devices.

As described above, the letter input method and system of the exemplary embodiments of the present invention is capable of simplifying a text input process and reducing text input time. Also, the letter input method and system is capable of minimizing a number of strokes required when inputting the same letter repeatedly. Also, the letter input method and system is capable of reducing the letter input time by negating a stroke and waiting time for confirming that an input letter is an intended letter.

The letter input method and system of the exemplary embodiments of the present invention is capable of inputting a letter by selecting a key to which the letter is assigned right after activating the toggle input mode with a single stoke, resulting in minimization of strokes required for inputting a text. Furthermore, the letter input method and system is advantageous in reducing input errors since there is no need to stroke the multi-letter key repeatedly to find the intended letter.

The above-described methods according to the present invention can be realized in hardware or as software or computer code that can be stored in a recording medium such as a Compact Disc (CD) ROM, an RAM, a floppy disk, a hard disk, or a magneto-optical disk or downloaded over a network, so that the methods described herein can be rendered in such software using a general purpose computer, or a special processor or in programmable or dedicated hardware, such as an Application Specific Integrated Circuit (ASIC) or Field Programmable Gate Array (FPGA). As would be understood in the art, the computer, the processor or the programmable hardware include memory components, e.g., a RAM, a ROM, a Flash, and the like that may store or receive software or computer code that when accessed and executed by the computer, processor or hardware implement the processing methods described herein. In addition, it would be recognized that when a general purpose computer accesses code for implementing the processing shown herein, the execution of the code transforms the general purpose computer into a special purpose computer for executing the processing shown herein.

While the invention has been shown and described with reference to certain exemplary embodiments thereof, it will be clearly understood by those skilled in the art that various changes in form and details may be made therein without departing from the spirit and scope of the invention as defined by the appended claims and their equivalents.

What is claimed is:

1. A letter input method for a mobile terminal, the method comprising:
activating a toggle input mode in response to a stroke on one of toggle keys;
detecting an input event on a letter key in the toggle input mode; and
inputting a letter which is fixed to the letter key in association with the toggle key activated in the toggle input mode among multiple letters assigned to letter keys.

2. The method of claim 1, wherein the activating of the toggle input mode comprises enabling a toggle key-specific toggle input mode in which the letters assigned to the letter keys with a priority order identical with an order of a selected toggle key are fixed.

3. The method of claim 2, wherein the inputting of the letter comprises repeating an input of the letter by as many times as a number of strokes occurred in the input event.

4. The method of claim 2, further comprising deactivating the toggle input mode in response to a stroke on the toggle key used for activating the toggle input mode.

5. The method of claim 2, wherein the toggle input mode is activated while a stroke made on the toggle key remains and is deactivated when the stroke is released.

6. The method of claim 5, further comprising inputting, if a stroke is detected on a letter key while the stroke made on the toggle key remains, the letter fixed to the letter key in association with the toggle key.

7. The method of claim 2, further comprising:
determining, if the input event is detected, whether the input event is detected on one of toggle keys arranged in a toggle key region; and
transitioning, if the input event is detected on one of the toggle keys, from a current input mode to the toggle input mode featured by the toggle key on which the input event is detected.

8. The method of claim 7, wherein the current input mode is one of a normal input mode and another toggle key-specific toggle input mode.

9. The method of claim 7, further comprising:
inputting, if the input event is detected on one of the letter keys arranged in a letter key region after transitioning from the current input mode to the toggle input mode, the letter fixed to the letter key on which the input event is detected in association with the toggle key activated in the current toggle input mode.

10. The method of claim 7, further comprising:
determining, if the detected input event occurred on a letter key, whether the toggle mode is activated;
verifying, if the toggle input mode is activated, the toggle key which activated the toggle input mode;
inputting a letter fixed to the letter key by the toggle key activated in the current toggle input mode; and
inputting, if the toggle input mode is deactivated, the letter determined by a number of strokes made on the letter key.

11. A letter input system for a mobile terminal, the system comprising:
a letter key region including a plurality of letter keys, each assigned at least one letter;
a toggle key region including at least one toggle key assigned an index representing an order of one of the at least one letter assigned to each letter key; and
a display region for illustrating letters input using the at least one toggle key and the letter keys.

12. The system of claim 11, wherein the at least one toggle key is equal to a maximum number of letters assigned to a single letter key.

13. The system of claim 12, wherein the at least one toggle key activates a toggle input mode and deactivates the toggle input mode according to an input event occurred on the toggle key.

14. The system of claim 13, wherein the display region displays, if an input event occurs repeatedly on a letter key while the toggle input mode is activated, the letter assigned to the letter key in an order represented by the index of the toggle key which is currently activated in the toggle input mode by as many times as the number of repetitions of the input event.

15. The system of claim 13, wherein the toggle input mode activates by enabling a toggle key-specific toggle input mode in which the letters assigned to the letter keys with a priority order identical with an order of a selected toggle key are fixed.

16. The system of claim 15, wherein the toggle input mode deactivates in response to a stroke on the toggle key used for activating the toggle input mode.

17. The system of claim 16, wherein the toggle input mode is activated while the stroke made on the toggle key remains and is deactivated when the stroke is released.

18. The system of claim 11, wherein the letter key region, the toggle key region, and the display region is provided on one of a display means and a input means of the mobile terminal.
